(19) United States
(12) Patent Application Publication
(10) Pub. No.: US 2026/0098905 A1
(43) Pub. Date: Apr. 9, 2026

(54) SYSTEM AND METHOD USING DATA-DRIVEN AUTOENCODER NEURAL NETWORK FOR ONBOARD BMS LITHIUM-ION BATTERY DEGRADATION PREDICTION

(71) Applicant: Purdue Research Foundation, West Lafayette, IN (US)

(72) Inventors: Vikas Tomar, West Lafayette, IN (US); Meghana Sudarshan, West Lafayette, IN (US); R. Edwin Garcia, West Lafayette, IN (US); Jaya Vikeswara Rao Vajja, West Lafayette, IN (US)

(73) Assignee: Purdue Research Foundation, West Lafayette, IN (US)

(21) Appl. No.: 19/348,735

(22) Filed: Oct. 2, 2025

Related U.S. Application Data
(60) Provisional application No. 63/703,580, filed on Oct. 4, 2024.
(60) Provisional application No. 63/703,594, filed on Oct. 4, 2024.

(51) Int. Cl. G01R 31/367; G01R 31/382; G01R 31/392; G06N 3/0455; G06N 3/08

(52) U.S. Cl. CPC G01R 31/367; G01R 31/382; G01R 31/392; G06N 3/0455; G06N 3/08

(57) ABSTRACT

A method of predicting battery end of life based on a small dataset includes training a deep learning network using a plurality of a priori generated training datasets, receiving new testing datasets including current vs. time datapoints in real-time as one or more batteries representing a battery pack design of choice are tested to thereby generate a plurality of new unseen datasets, and applying the new unseen datasets to the trained deep learning network to thereby generate a prediction of a cycle representing end of life for said design of choice.

### CROSS-REFERENCE TO RELATED APPLICATIONS

The present non-provisional patent application is related to and claims the priority benefit of U.S. Provisional Patent Application Ser. 63/703,580, filed Oct. 4, 2024, and also claims the priority benefit of U.S. Provisional Patent Application Ser. 63/703,594, filed Oct. 4, 2024, the contents of each of which are hereby incorporated by reference in its entirety into the present disclosure.

### STATEMENT REGARDING GOVERNMENT FUNDING

This invention was made with government support under N00014-22-1-2079 awarded by the Office of Naval Research. The government has certain rights in the invention.

### TECHNICAL FIELD

The present disclosure generally relates to a system and method for testing batteries, and in particular using a battery management system (BMS) and a small dataset for predicting end of life (EOL) of Lithium-ion based batteries (LIBs).

### BACKGROUND

This section introduces aspects that may help facilitate a better understanding of the disclosure. Accordingly, these statements are to be read in this light and are not to be understood as admissions about what is or is not prior art.

Technologies running on LIB are nowadays widespread. These technologies range from electric and hybrid land-based vehicles to unmanned aerial vehicle drones and to a large number of other devices including medical equipment. While there are a number of failure modes that have been documented over the last 2 or more decades, the typical charge and discharge cycles in LIBs result in normal degradation of the LIB over hundreds and thousands of such cycles. Therefore, usage of LIBs must be continuously monitored to maintain safe operation and to prolong life by understanding the capacity degradation as a function of battery aging. Monitoring is performed using a non-invasive measurement of current (I) using a BMS. The BMS estimates battery life by tracking the remaining capacity in the form of quantities such as state of charge (SoC) which refers to the percentage of the ratio of charge capacity at that time to the maximum possible charge it can hold, and state of health (SoH) which refers to the maximum possible charge a battery can hold in comparison to the rated capacity. These performance-determining factors can be used to determine the number of cycles remaining before reaching the EOL, also called the remaining useful life (RUL). Typically, EOL is considered to be 0.8 Qₙₒₘᵢₙₐₗ (i.e., 80% of nominal capacity) translating to 20% degradation in the battery capacity. This definition of SoH does not account for the history-dependent nature of battery degradation under various abusive cycling conditions, such as high charge-discharge rates, and wide variety of operation temperatures.

Capacity loss due to aging of LIBs has been studied extensively as a combination of an initial quasi-linear stage and steep accelerated nonlinear trends. Examples of these multi-stage aging trends can be observed in FIGS. 1a and 1b which are plots of capacity in ampere-hour (Ah) vs. cycle number for three different cathode cell chemistries (Nickel Manganese Cobalt Oxide (NMC) and Nickel Cobalt Aluminum Oxide (NCA) in FIG. 1a; and Lithium Iron Phosphate (LFP) in FIG. 1b) from an experimental study conducted by Sandia National Lab. These figures show distinct multi-stage degradation trends with reference to cell chemistries, a phenomenon due to chemical reactions within LIBs known in the prior art. The data characterizes capacity fade in LIBs with three stages: 1) an acceleration stage due to sudden Lithium loss showing a steep dip, 2) a stabilization stage with solid-electrolyte interphase thickening and side reaction decay, and 3) a saturation stage with active material loss. Various causes for the switch between different capacity fade stages that have been proposed are based on multiple coupled degradation mechanisms and are specific to cathode cell-chemistries in LIBs. Specifically, researchers have described cell chemistry and operational conditions affecting the path towards EOL and exact degradation mechanisms of LIBs. Such trends with cell chemistry can also be identified in many other publicly available datasets from various organizations such as National Aeronautics and Space Administration Prognostics Center of Excellence (PCoE), National Renewable Energy Laboratory repository, Hawaii Natural Energy Institute, University of Maryland, and Oxford University to name a few. However, a universal solution for capacity degradation that can adapt to any cell chemistry is yet to be found. Furthermore, cycle testing requires a long period of time. Assuming each cycle requires about one day, cycle time for batteries requiring thousands of cycles requires many years of testing.

Therefore, there is an unmet need for a novel system and a method for predicting EOL that is capable of handling many different chemistries with a reduced dataset.

### SUMMARY

A method of predicting battery end of life based on a small dataset is disclosed. The method includes training a deep learning network using a plurality of a priori generated training datasets, receiving new testing datasets including current vs. time datapoints in real-time as one or more batteries representing a battery pack design of choice are tested to thereby generate a plurality of new unseen datasets, and applying the new unseen datasets to the trained deep learning network to thereby generate a prediction of a cycle representing end of life for said design of choice.

A system for predicting battery end of life based on a small dataset is also disclosed. The system includes one or more current sensors providing real-time current data, a testbed configured to test one or more batteries based on a prescribed testing schedule, and a processing system including a processor executing instruction residing on a non-transitory memory. The processor is configured to receive real-time current data, and the processor is configured to communicate with a deep learning network. The processor is further configured to train the deep learning network using a plurality of a priori generated training datasets, receive new testing datasets in real-time including current vs. time datapoints as one or more batteries representing a battery pack design of choice are tested to thereby generate the new unseen datasets, and apply the new unseen datasets to the trained deep learning network to thereby generate a prediction of a cycle representing end of life for said design of choice.

### BRIEF DESCRIPTION OF DRAWINGS

FIGS. 1a and 1b which are plots of capacity in ampere-hour (Ah) vs. cycle number for three different cathode cell chemistries (Nickel Manganese Cobalt Oxide (NMC) and Nickel Cobalt Aluminum Oxide (NCA) in FIG. 1a; and Lithium Iron Phosphate (LFP) in FIG. 1b) from an experimental study conducted by Sandia National Lab.

FIG. 2 is a block diagram of a system according to the present disclosure having several components shown therein.

FIG. 3 is an example block diagram showing exchange of information in a neural network first during the training phase where the network is trained with a priori information, and then during testing phase, when the network is provided previously unseen data used by the network to provide a prediction as well as optionally monitor safety concerns.

FIG. 4 is a schematic of the neural network, according to the present disclosure, which shows a CD-Net, combining a sequential autoencoder with a perceptron to predict the LIB battery health during battery operation from battery management system (BMS) outputs.

FIGS. 5a and 5b provide graphs of MSE loss vs. Epochs, which show bias-variance tradeoff curves during training of CD-Net showing train-test loss with epochs on semi-log plot and inset plot using Mean square error (MSE) (FIG. 5a) and Mean absolute error as loss functions (FIG. 5b).

FIGS. 6a, 6b, and 6c are graphs of capacity (Ah) vs. equivalent cycles, which show capacity degradation curve predictions with incorporation of cell chemistry on CD-Net on Lithium-ion based battery (LIB) cell-chemistries in which NCA (FIG. 6a), NMC (FIG. 6b), and LFP (FIG. 6c) are provided in said figures.

FIG. 7 is a graph of relative improvement vs. cell chemistry, improvement in SoH prediction in a violin plot using CD-Net-cc (with cell chemistry information) in comparison to baseline model CD-Net (without cell chemistry information) for NCA, NMC, and LFP cell chemistries showing the effect of model training with cell chemistry information on capacity prediction.

FIG. 8 is a graph of capacity in Ah vs. cycle number, for one test case of the B0006 dataset.

FIG. 9 is a graph of train time in seconds vs. predicted time latency in us vs. network type.

### DETAILED DESCRIPTION

For the purposes of promoting an understanding of the principles of the present disclosure, reference will now be made to the embodiments illustrated in the drawings, and specific language will be used to describe the same. It will nevertheless be understood that no limitation of the scope of this disclosure is thereby intended.

In the present disclosure, the term “about” can allow for a degree of variability in a value or range, for example, within 15%, within 10%, within 5%, or within 1% of a stated value or of a stated limit of a range.

In the present disclosure, the term “substantially” can allow for a degree of variability in a value or range, for example, within 85%, within 90%, within 95%, or within 99% of a stated value or of a stated limit of a range.

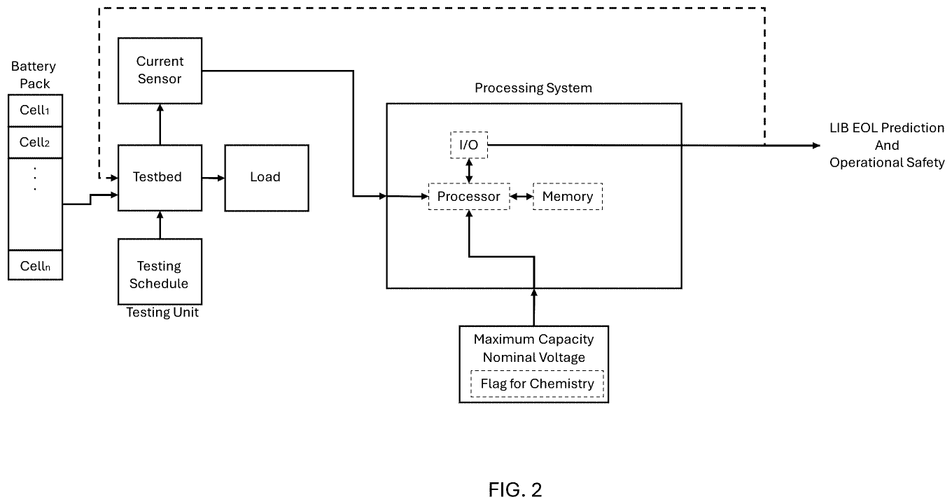

A novel system and a method for predicting end of life (EOL) that is capable of handling many different chemistries with a reduced dataset is presented herein. Towards this end, reference is made to FIG. 2, which is a block diagram of a system according to the present disclosure having several components shown therein. FIG. 2 provides a battery pack comprised of a plurality of cells (Cell₁, Cell₂, . . . . Cellₙ) coupled to a test bed for testing one or more of the plurality of cells. The test bed is coupled to a testing unit providing a testing schedule. The test bed is also coupled to a load intended to discharge the one or more cells of the plurality of cells. Additionally, a current sensor, e.g., a sense resistor, or an ammeter, is coupled to the test bed to measure current drawn out of the one or more cells of the plurality of cells. The test bed is therefore responsible for cycling the one or more cells, which is charging and discharging in a cyclical manner. Output of the current sensor is provided to a processing system having a processor, e.g., a micro-controller with one or more analog to digital converters, a micro-processor coupled to a standalone analog to digital converter (not shown), a digital signal processor, a field programmable gate array, etc. The current data which is an analog signal is converted to a digital signal and is time-stamped to generate current in ampere vs. time in seconds, which is then converted to capacity which is a measure of charge accumulation or discharge as a function of time (typically provided as ampere hour) vs. cycle. The processing system further may include a memory block (shown as an off-chip memory or can be an on-chip memory on the processor) having non-transitory memory for storing instructions are executed by the processor to carry out the method of the present disclosure. Additionally, the processing system may include an input-output (I/O) block in communication with the processor and capable of providing an output representing prediction of EOL by the system of the present disclosure. Additionally, the I/O block may optionally receive signals from the processor related to safety parameters that can be provided as real-time feedback to the test bed, thus stopping the testing procedures enabled by the testing unit when such parameters indicate safety issues. Additionally, the processing system receives various information about the battery pack such as maximum capacity, nominal voltage, and optionally a flag indicating the type of cathode chemistry for the battery under test.

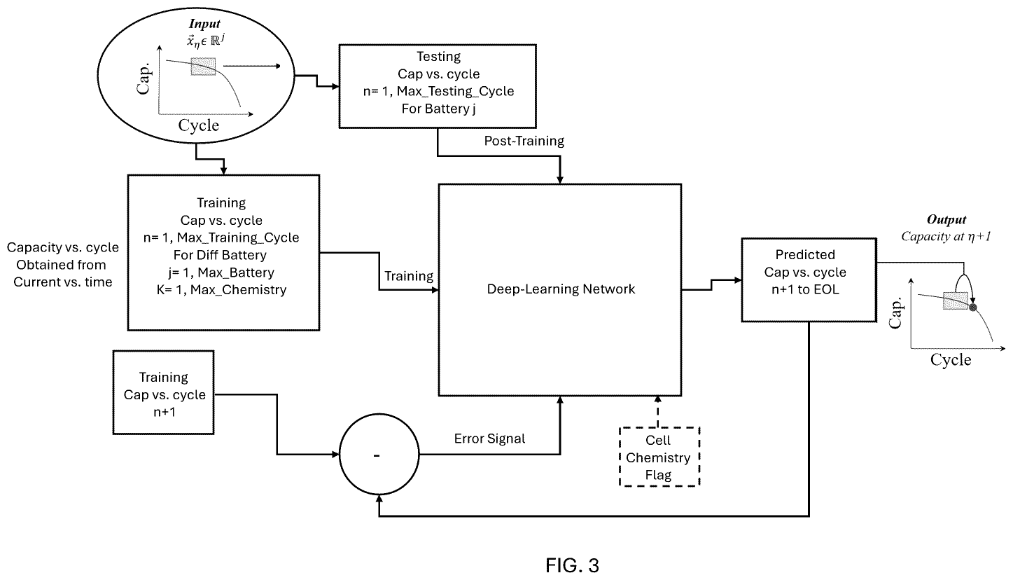

The processor and memory, according to the present disclosure provide a machine learning methodology often referred to as a deep learning network. Such a network uses interconnected nodes in a layered structure (e.g., an input layer, hidden layers, and an output layer) connected via a large number of connections with associated weights, as is known to a person having ordinary skill in the art. One example is a neural network. Referring to FIG. 3, an example block diagram is provided showing exchange of information in such a network first during the training phase where the network is trained with a priori information, and then during testing phase, when the network is provided previously unseen data used by the network to provide a prediction as well as optionally monitor safety concerns.

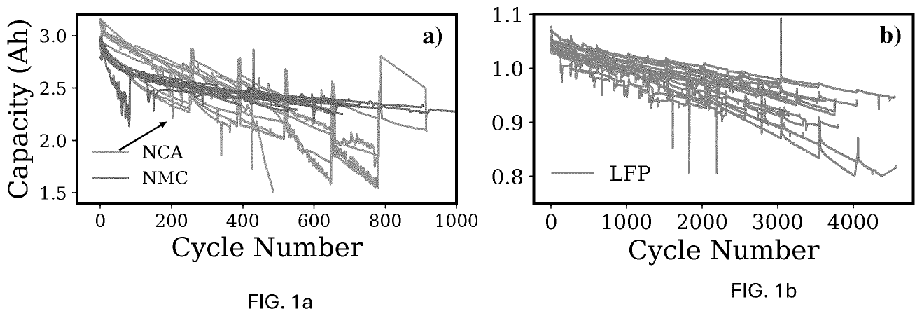

Referring to FIG. 3, large training data is provided to the deep learning network. For example, there may be 2000 cycles for a particular type of battery chemistry (e.g., Nickel Manganese Cobalt Oxide (NMC) and Nickel Cobalt Aluminum Oxide (NCA), see e.g., FIG. 1a, Lithium Iron Phosphate (LFP), see e.g., FIG. 1b, to name a few such chemistries. As alluded to above, capacity vs. cycle may be provided in the form current vs. time, or simply capacity vs. cycle, however, the former is convertible to the latter. The deep learning network may receive the large capacity vs. cycle training data in a chemistry-independent fashion, i.e., some training sets may be for one chemistry and other training sets for other chemistry. Alternatively, the training dataset may be accompanied by a cell chemistry flag to train the network specifically for each type of chemistry. For example, if there are four different chemistries of interest, a 2-bit flag may be used to train the network with selective datasets for the associated chemistries. Regardless of whether chemistry-selective or chemistry-independent, the network is trained with a large dataset (e.g., 2000 cycles) for each type of chemistry, based on a large number of battery datasets for each type of chemistry (that is, for, e.g., LFP battery chemistry, 4000 cycles of capacity data is presented to the network (i.e., Max_Training_Cycle=4000), and 80 datasets of capacity vs. cycle from 80 different, e.g., LFP, batteries (i.e., Max_Battery=80) is presented, e.g., each having 4000 cycles). There may be 4 different types of battery chemistry (i.e., Max_Chemistry=4). Generally, the network generates future capacity vs. cycle predictions up to EOL (e.g., 80% capacity of maximum capacity). During the training, predicted values from the network are used as feedback against the a priori training data to generate an error signal that can be used to update the network, e.g., the weights. Once the training is complete, the network may be tested (not shown) with known additional capacity vs. cycle data to ensure network output is indeed in compliance with the additional capacity vs. cycle data based on predicted values. These additional datasets represent unseen data; however, this unseen data (not shown) still represents part of testing of the network.

When satisfied with the testing phase, the system and the method of the present disclosure provides unseen novel data that is provided in much smaller sizes. For example, capacity vs. cycle novel data may be for only, e.g., 80 LFP cycles, requiring a much shorter testing period (i.e., days vs. years). This dataset is shown in the Testing block providing post training datasets, including capacity vs. cycle for n=1 to Max_Testing_Cyle (e.g., 80) for a specific battery (shown as Battery j) with or without a battery chemistry flag, depending if the network is trained based on a chemistry-specific or chemistry-independent regime as discussed above.

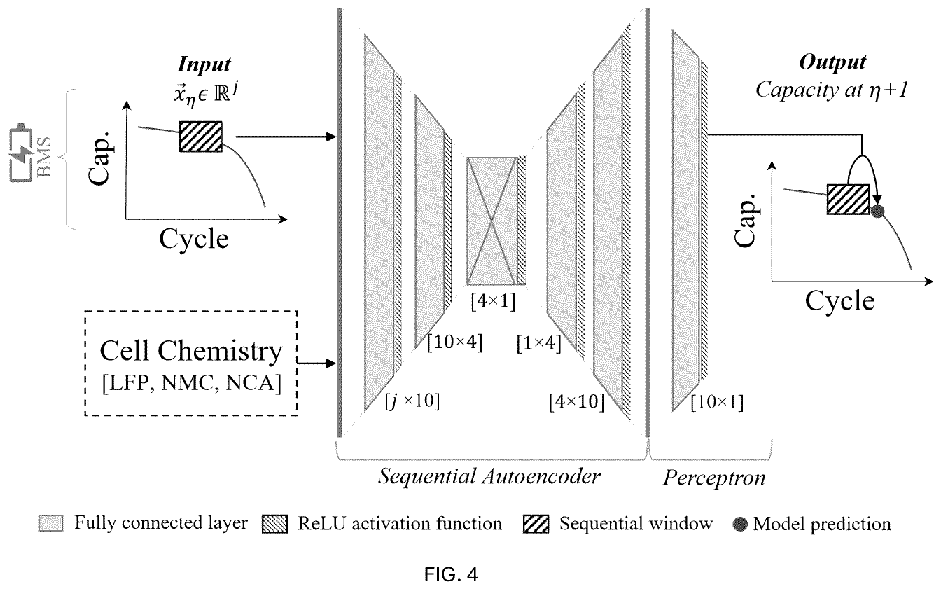

Selectively, various parameters can be chosen in variation of data during the training phase. These variables may include ambient temperature at which the battery is operated in, charge or discharge voltage of the battery, current drawn from or inputted into the battery during the discharge or charge cycles, C-rate ((defined as the discharge or charge current)/battery capacity), discharge range (e.g., about 20% to about 80% or 0% to 100%), rest period (defined as amount of time between discharge and charge cycles), mechanical stress including vibration, impact force on battery, presence of a knee (see FIG. 4, where a sudden precipitous drop is shown in capacity vs. cycle, referred to as the “knee”), cell chemistry, relative battery position during lifecycle of the battery, and environmental conditions including humidity, ambient air pressure, and ambient temperature (discussed above). Each of these listed parameters can be weighted for amount of data used during the training phase. For example, more of the training data can be from variations in temperature than mechanical stress. Similarly, more of the training data can come from latter part of the lifecycle of the battery than when the battery is new. That is, suppose end of life of battery is designated as the battery's ability to hold about 80% of the initial capacity when the battery was first placed in service. More data during training can come from batteries close to the 80% mark than 100% mark. Furthermore, after the training, in operation, the data provided to the neural network may be uniformly distributed.

The weighted data, discussed herein, are to be distinguished from weights of the neural network, i.e., connectivity weights between the node. For the neural network, outputs y′ of each layer λ with a weight vector wᵢ for each node i and layer bias vector b is given as the equation below, where ƒ is a rectified linear activation function used after each layer to ensure that the final capacity outputs are purely positive.

$${y}^{′} = {\sum }_{n o d e s} f ( {w}_{i} \cdot {y}_{λ - 1}^{′} + b )$$

Given the inputs for the model's initial capacity, cycle number, capacity of current cycle for a sequential window of 4 cycles are used to predict the upcoming cycle capacity and predictions up to end of life of battery. If a battery exhibits a knee point, the model keeps on predicting the next cycle and model predictions get closer because of squared error loss function used:

$$L = \frac{1}{n} {\sum }_{samples} {( {y}_{η} - {\hat{y}}_{η} )}^{2} where {\hat{y}}_{η} = {k}_{δ} ( {h}_{θ} ( {g}_{ϕ} ( {\vec{x}}_{η} ) ) )$$

FIG. 4, which is a schematic of the neural network, according to the present disclosure, shows a CD-Net, combining a sequential autoencoder with a perceptron to predict the Lithium-ion based battery (LIB) battery health during battery operation from battery management system (BMS) outputs. To transform BMS data into the next cycle SoH, CD-Net uses its hidden layer nodes to capture temporal vectors responsible for multi-stage degradation with cycling. The inputs to the CD-Net consist of sequential historical data for capacity-cycle with information on cell chemistry and rated nominal capacity of the cell. The kernel sizes for this architecture used in this work are reported at each layer of sequential autoencoder and perceptron. The autoencoder of CD-Net is responsible to denoise capacity data and emphasize the temporal aspects of multi-stage degradation by using sequential history data from previous cycles of the battery into an encoder-decoder architecture.

CD-Net uses cell features (C_{α}) and cycle features (C_{γ}) as inputs for capacity prediction of the next cycle. Cell features C_{α} includes rated nominal capacity of selected LIB dataset and optional cell chemistry information. For this work, two versions of CD-Net are used to study the effect of training with cell chemistry, CD-Net-cc and CD-Net. CD-Net-cc corresponds to the same CD-Net architecture with the addition of input of cell chemistry into C_{α}. Cycle features C_{γ} refers to capacity variation of LIB throughout its cycle life, where γ as the total number of cycles and cycle capacity at each cycle c₁, c₂, . . . , c_{γ}∈C_{γ}. At a given cycle η, C_{γ} consists of historical capacity data of sequential window ω, where C_{γ}_{_{η}}={c_{η}, C_{η-1}, . . . , C_{η-ω}}. From the input samples, specific input x_{η} at cycle η with a j total features into model are given by,

$${\vec{x}}_{η} = \{ {C}_{a} , {C}_{{γ}_{η}} \} where {\vec{x}}_{η} {ϵℝ}^{j} \qquad ( 1 )$$

Within the model architecture, the outputs y′ of each layer λ with a weight vector wᵢ for each node i and layer bias vector b is given as

$${y}_{λ}^{λ} = {\sum }_{n o d e s} f ( {w}_{i} \cdot {y}_{λ - 1}^{′} + b ) .$$

Here ƒ is a rectified linear activation function used after each layer to ensure that the final capacity outputs are purely positive. At the end of each training epoch, the model uses a mean squared error as a loss function (L) for n number of samples on input X where model prediction ŷ_{η} at η cycles is compared with ground truth values (y_{η}) considered from experimental data.

$$L = \frac{1}{n} {\sum }_{s a m p l e s} {( {y}_{η} - {\hat{y}}_{η} )}^{2} where {\hat{y}}_{η} = {k}_{δ} ( {h}_{θ} ( {g}_{ϕ} ( {\vec{x}}_{η} ) ) ) \qquad ( 2 )$$

Where, ŷᵢ is the model prediction for input \vec{x}_{ι} where k_{δ} represents δ number of layers of perceptron k, g_{φ} represents φ number of layers of encoder g, h_{θ} represents θ number of layers of the decoder h.

To evaluate the performance of the model, experimental RUL (η_{RUL}) is compared with model prediction \hat{η}_{RUL} using mean absolute error |η_{RUL}−\hat{η}_{RUL}|. Another evaluation metric used to compare the two models CD-Net and CD-Net-cc in the effect of training with cell chemistry information is with relative percentage improvement (RI). It is defined as the difference in MAE of CD-Net with CD-Net-cc normalized over their cell chemistry specific capacity range of the LIB, where (1) refers to CD-Net-cc and (2) refers to CD-Net.

$$RI = \frac{\vert {y}^{( 1 )} - {\hat{y}}^{( 1 )} \vert - \vert {y}^{( 2 )} - {\hat{y}}^{( 2 )} \vert}{( C a {p}_{. max} - Cap {.}_{min} )} \times 100 \qquad ( 3 )$$

The quality of training data heavily influences the accuracy of a machine learning model. The available data was classified based on the possibility to obtain maximum information on the state of the battery from external battery outputs, such as current, voltage, and temperature, that mimic BMS data. The main classification factors include the availability of cell temperature data, cell chemistry, cell form factor, ambient temperatures, charge/discharge rates, and minimum-maximum state of charge. After classification, the SNL dataset is used to study the effect of cell chemistry, and the NASA PCoE dataset is used to assess the online performance of the proposed model.

To understand the effect of cell chemistry in the prediction of SoH, cell chemistry is used as a fitting parameter in the proposed neural network architecture. The cathode cell-chemistries included are LFP, NMC, and NCA. Datasets provided by SNL are shown in FIGS. 1a and 1b, where the capacity fade is plotted as a function of the number of cycles. It is observed that different cell chemistries take a different number of equivalent full cycles to reach a level of 20% capacity fade with NCA, NMC, and LFP order being from the least to the highest number of cycles, respectively. Here, equivalent full cycle refers to the total discharge capacity per Qₙₒₘ. All cells were charged at 0.5 C and discharged at 0.5 C, 1 C, 2 C, and 3 C for various extents of SOC including 40-60%, 20-80%, and 0-100% at temperatures of 25° C., 15° C., 35° C. from 0-100% state of charge at 0.5 C. The main reason for the usage of this dataset in the effect of cell chemistry study is the availability of cell chemistry information for all the cycled cells.

For the analysis of the performance of SoH prediction model onboard BMS, various ML methods were compared on NASA PCoE datasets. The datasets consist of aging data for 2 Ah 18650 LIBs at different operational conditions. The cell chemistry information of the cycled LIBs was not specified for this dataset. They were charged with a constant current constant voltage (CC-CV) profile with CC of 1.5 A till 4.2 V and then held at a CV until the current dropped to 20 mA. Batteries were discharged at a constant current of 2 A until a lower cutoff voltage of 2.5V, 2.7V, 2.2V, and 2.5V was reached for B0005, B0006, B0007, and B0018 respectively. The cycle process continued until a 30% capacity fade was observed. The datasets provided time-based measurements for V, I, and T within each cycle and cycle-based capacity measurements.

In a BMS, one of the primary objectives is to maintain a safe operating envelope for the battery pack by monitoring its inflow of charge and discharge current (I), voltage (V), and external temperature (T), and SoH. With every charge and discharge cycle, the capacity values of LIBs degrade, thus decreasing the SoH. Data-driven ML algorithms are used to estimate the SoH by predicting the number of remaining charge-discharge cycles required before the LIBs become unusable.

The flow of data from a battery pack to a BMS for prediction of RUL is used to estimate LIB capacity as a function of time. In this paper, the LIBs are assumed to start from a maximum charge state of 100%. The time-dependent capacity estimate is used in a cycle-based capacity forecast to predict the number of cycles left before a battery reaches EOL, defined herein as 80% of its original capacity. For the onboard diagnosis of aging, the SoC of a battery at time t is determined by coulomb counting given by

$$S o {C}_{t} = S o {C}_{0} + {\int }_{0}^{t} \frac{{i}_{t}}{{Q}_{n o m}} d t$$

where Qₙₒₘ is the nominal capacity of the un-aged battery and SoC, is the initial SoC. As the SoC completes an equivalent cycle from a fully charged 100% to a fully discharged 0% SoC, the SoH at that current state is calculated by comparing the maximum capacity in the current cycle with fresh uncycled LIB given by

$$S o H = \frac{{Q}_{max}}{{Q}_{nominal}} where {Q}_{max}$$

is the maximum capacity reached in a given cycle. The capacity degradation curve is plotted as a function of the number of equivalent cycles by obtaining the maximum capacity achieved for a particular cycle. The SoH metric reflects the performance of the used LIBs in comparison to unaged batteries.

CD-Net numerical implementation consists of a five-layer sequential autoencoder with (10×4×1×4×10) neurons and a two-layer perceptron network. After analyzing the bias-variance convergence plot, CD-Net is trained for 20 epochs with a learning rate of 104 using Adam's optimizer. For the cell-chemistry-based study, CD-Net-cc is provided with information on cell chemistry using the one-hot encoding technique where different numeric values are assigned to cell-chemistries. CD-Net-cc corresponds to the same CD-Net implementation parameters. Both CD-Net and CD-Net-cc are implemented on the PyTorch 1.11.0 framework.

Online prediction of the performance of CD-Net is compared with SVR, BR, and GPR predictions on the same data. The SVR model was defined with a radial basis function kernel with a multi-output regressor, regularization parameter of 20, ∈ of 0.0001, and γ of 0.00001. GPR was initiated with radial basis function kernel, rational quadratic, exponential sine squared, followed by a Matern kernel. The BR samples were drawn from a uniform distribution with the application of a grid search method over 100 iterations. SVR, BR, and GPR were implemented using Scikit-learn 1.0.1 package. Training and testing datasets used for this paper, with other model information including input and output features are mentioned in Table 1. For a fair comparison of evaluation of the performance of CD-Net with other models, the leave-one-out cross-validation method (also known as the out-of-sampling technique) was used. Here, the models were trained on all datasets except for the one test dataset followed by a prediction for the same remaining test dataset. All the models were run on Python 3.7 with 16 GB RAM and Intel 11^{th} Gen Core i7-118G7 @ 3.00 GHz CPU on Ubuntu 22.04 operating system.

TABLE 1
Battery cycling datasets and information on
ML methods used in the present disclosure.

| | |
|---|---|
| Datasets | NASA B0005, B0006, B0007, B0018 |
| | Sandia National Labs: LFP, NCA, NMC |
| Model input | Cycle number |
| | State of Charge |
| | Nominal Capacity |
| | Cell Chemistry |
| Methods | Gaussian process regressor (GPR) |
| | Support vector regressor (SVR) |
| | Bayesian regressor (BR) |
| | Proposed Network (CD-Net) |
| Sequential window | 4 cycles |
| Output features | Battery Capacity |

The performance of CD-Net was assessed in an online prediction setting in a chemistry independent setting as well as in a cell chemistry information setting. In an online prediction setting, the performance of cell chemistry-independent CD-Net is compared with online SoH estimation methods (SVR, GPR, and BR) from previous literature.

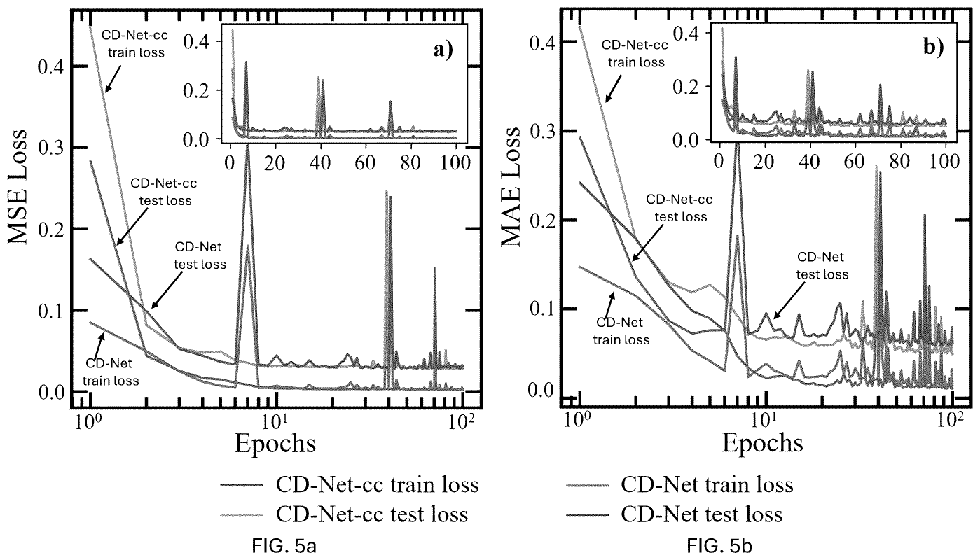

FIGS. 5a and 5b, which provide graphs of MSE loss vs. Epochs, show bias-variance tradeoff curves during training of CD-Net showing train-test loss with epochs on semi-log plot and inset plot using Mean square error (MSE) (FIG. 5a) and Mean absolute error as loss functions (FIG. 5b). A tradeoff convergence at 20 training epochs in the case of CD-Net-cc (with cell chemistry) and CD-Net (without cell chemistry) can be observed.

The effect of cell chemistry information on CD-Net prediction accuracy is measured with the mean absolute RUL error indicator. Datasets from Sandia National Labs were used to evaluate generalization capabilities of CD-Net on various cell chemistries such as LFP, NCA, and NMC. CD-Net was trained on the cycle number, SoC, and nominal capacity of batteries for the SNL dataset. Throughout this section, CD-Net trained with cell chemistry information is referred to as CD-Net-cc and CD-Net trained without cell chemistry information is referred to as CD-Net. The minimum number of epochs necessary to train CD-Net and CD-Net-cc in order to minimize the loss function and RUL error was determined by using the loss data presented in FIGS. 5a and 5b. Its analysis shows that equation 2 for both training and testing converge to their lowest values at 20 epochs for MAE and 10 epochs for MSE, indicating a favorable bias-variance tradeoff. Consequently, the number of training epochs was selected as 20 for both CD-Net and CD-Net-cc.

TABLE 2
A comparison of average remaining useful life (RUL) error
for CD-Net (without cell chemistry) and CD-Net-cc (with cell
chemistry) trained on SNL dataset - LFP cell chemistry does
not reach its end of life (EOL) in tested datasets.

| | | |
|---|---|---|
| Cathode Cell | CD-Net-cc | CD-Net |

| Chemistry | RUL Error | MSE | RUL Error | MSE |
|---|---|---|---|---|
| NCA | 3 | | 3 | |
| NMC | 4 | | 4 | |
| LFP | N/A | | N/A | |

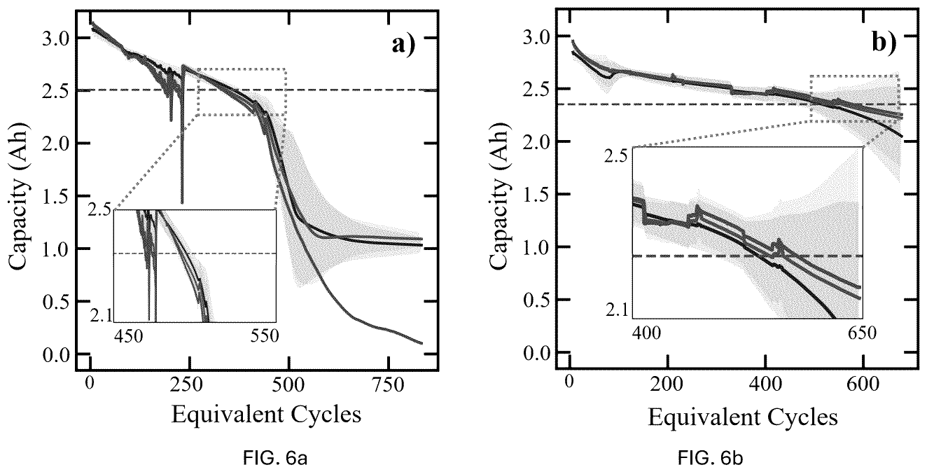

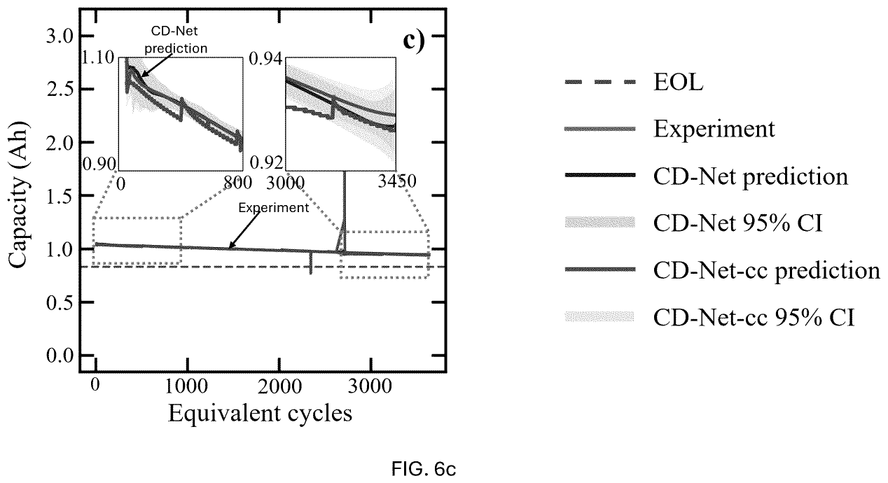

Referring to FIGS. 6a, 6b, and 6c which are graphs of capacity (Ah) vs. equivalent cycles, capacity degradation curve predictions with incorporation of cell chemistry on CD-Net on LIB cell-chemistries are provided in which NCA (FIG. 6a), NMC (FIG. 6b), and LFP (FIG. 6c) are provided in said figures. Here CD-Net-cc refers to CD-Net trained with information on cell chemistry of LIB. Inset plots show predictions of CD-Net and CD-Net-cc around end of life (EOL) in NCA and NMC. LFP inset plots show the capacity predictions at the beginning and end of cycling. “True” label refers to the experimental values of capacity reported in the respective datasets.

The trained CD-Net and CD-Net-cc models were tested using leave-one-out cross-validation to predict battery capacity for the upcoming charge-discharge cycle. The average RUL error with observed (real) data is reported in Table 3. FIGS. 6a, 6b, and 6c illustrate the projected battery capacity for a distinct dataset representative of each cell chemistry. The 95% confidence bounds are established using model predictions derived from the model trained through 100 sampling iterations. In terms of model train time, CD-Net takes t=370.24±10.83 s and CD-Net-cc takes t=372.31±8.46 s. From Table 3 and FIGS. 6a, 6b, and 6c, it can be observed that the average RUL error in the case of CD-Net-cc predictions is lower than CD-Net for all three chemistries. Even though LFP cells do not reach EOL from the capacity curves (denoted by N/A in Table 3), CD-Net-cc (model with cell chemistry information) predicts degradation curves closer to true values than CD-Net (model without cell chemistry information). In terms of RUL error prediction reported in Table 3, NCA and NMC cells reach their EOL whereas LFP cells do not in the considered dataset. For NMC (FIG. 6b), CD-Net and CD-Net-cc predict capacity with 0.071 and 0.066 MSE respectively with true values throughout cycle life. For and LFP (FIG. 6c), CD-Net and CD-Net-cc predict capacity with 0.008 and 0.006 MSE respectively. In FIG. 6a for NCA cell chemistry, it is observed that the battery capacity is predicted close to the true value until ˜450 cycles with MSE values of 0.082 and 0.070 for CD-Net and CD-Net-cc respectively. NCA shows three-stage capacity degradation in the considered dataset and CD-Net poorly predicts the last stage of degradation. Overall, for all three cell-chemistries, capacity predictions with CD-Net-cc are closer to true values of capacity degradation.

TABLE 3
Comparison of average remaining useful life (RUL) error
using various ML methods for 20% capacity degradation
with NASA dataset using leave-one-out cross-validation.

| Evaluated Models | RUL Error (Cycles) |
|---|---|
| SVR | 10.2 |
| BR | 19.2 |
| GPR | 8.5 |
| CD-Net | 3.7 |

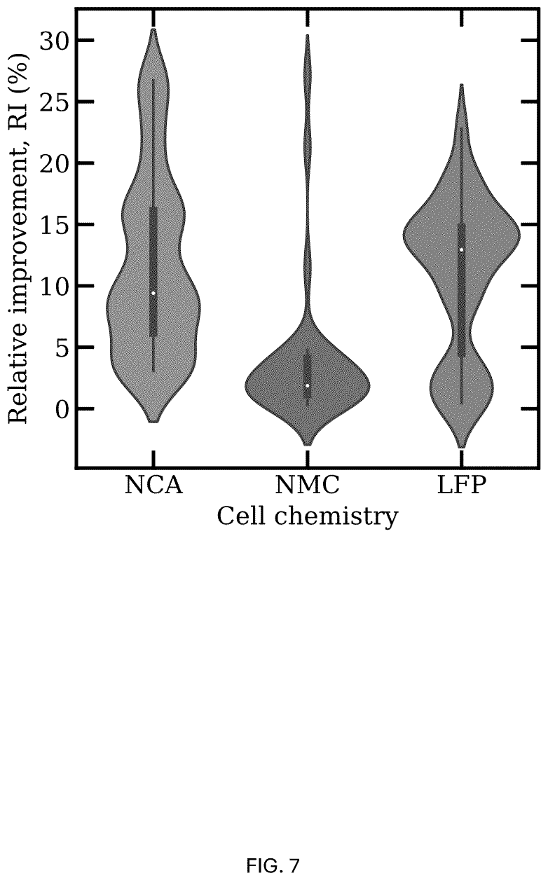

To further evaluate the improvement in model prediction with the incorporation of cell chemistry during CD-Net training, the relative percentage improvement (RI) in RUL prediction using CD-Net-cc vs CD-Net is shown in FIG. 7. Referring to FIG. 7, which is a graph of relative improvement vs. cell chemistry, improvement in SoH prediction in a violin plot using CD-Net-cc (with cell chemistry information) in comparison to baseline model CD-Net (without cell chemistry information) for NCA, NMC, and LFP cell chemistries showing the effect of model training with cell chemistry information on capacity prediction. LFP improvements are concentrated among two distributions, ˜15% and ˜2% whereas NMC shows ˜2% improvement with 3 major outliers reaching up to 28%. CD-Net-cc shows significant improvement in the case of all three cell-chemistries. LFP cell chemistry shows the greatest improvement with 12.6%, followed by NCA at 5.2% and NMC at almost 2% in comparison to the baseline model CD-Net, where cell chemistry information is not used within the network. From the above results, it can be concluded that the neural network model with cell chemistry information (CD-Net-cc) captures the capacity fade curve more accurately. After training and deployment of the models onboard BMS, deployability characteristics such as prediction time (inference latency) and onboard storage space are captured to assess their computational lightness. Specifically, CD-Net-cc demonstrates a prediction time of 70.13±21.51 μs, while CD-Net exhibits a prediction time of 68.58±17.05 us per input across 1000 trails on the computer setup described in Section 4. Regarding storage space, both models require 3.5 KB of space, irrespective of the size of the training dataset as the number of trainable parameters within the model remains similar. Considering the similarity in deployability characteristics, the accuracy vs computational lightness choice between the two models is based solely on the method's prediction accuracy. Thus, it can be inferred that the model trained with cell chemistry information is more robust for predicting battery capacity across various cell chemistries and can be readily deployed on a BMS.

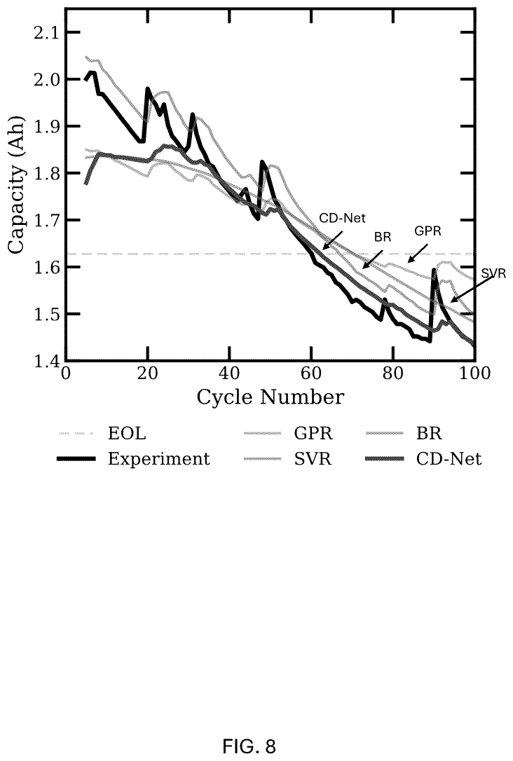

In operation, use of CD-Net on a BMS is evaluated in terms of RUL prediction accuracy and computational efficiency based on the NASA PCoE datasets. The NASA datasets used for this section do not provide any information on cell chemistry; thus, the CD-Net architecture (without the cell chemistry feature) is used for the evaluation of online prediction. CD-Net prediction is also compared with predictions from SVR, BR, and GPR trained on the same NASA battery cycling datasets with leave-one-out cross-validation sampling for each dataset. The average RUL error for CD-Net in comparison to SVR, BR, and GPR using leave-one-out cross-validation is reported in Table 3. As shown, CD-Net has the least error, thus the most accuracy, closely followed by GPR, SVR, and BR. To better visualize this, a comparison of model performances of CD-Net, SVR, BR, and GPR is shown in FIG. 8, which is a graph of capacity in Ah vs. cycle number, for one test case of the B0006 dataset. Here, the dotted reference EOL line represents 80% nominal capacity. Onboard capacity degradation performance of CD-Net, SVR, BR, and GPR on NASA B0006 dataset. End of life (EOL-dotted line) is considered to be at 20% capacity degradation and “True” represents the experimentally measured capacity values reported in the dataset. For this dataset, given a sequential input of 4 equivalent cycle capacities, it is observed that the CD-Net performs the best in terms of prediction of LIB capacity at EOL. BR model best captures the historical trend including seasonality patterns of capacity degradation with an offset. The SVR model predicts LIB capacity with an offset error from the curve other than at ˜85% nominal capacity whereas the GPR model poorly predicts local curve features. Even though GPR is close in RUL error to CD-Net, GPR primarily uses whole data features for curve fitting during training, making it susceptible to outliers and noise in the dataset. Therefore, GPR accuracy can suffer from outliers with any noisy onboard BMS data. From these results, we can conclude that the proposed network has a higher accuracy than compared models for all examined NASA datasets.

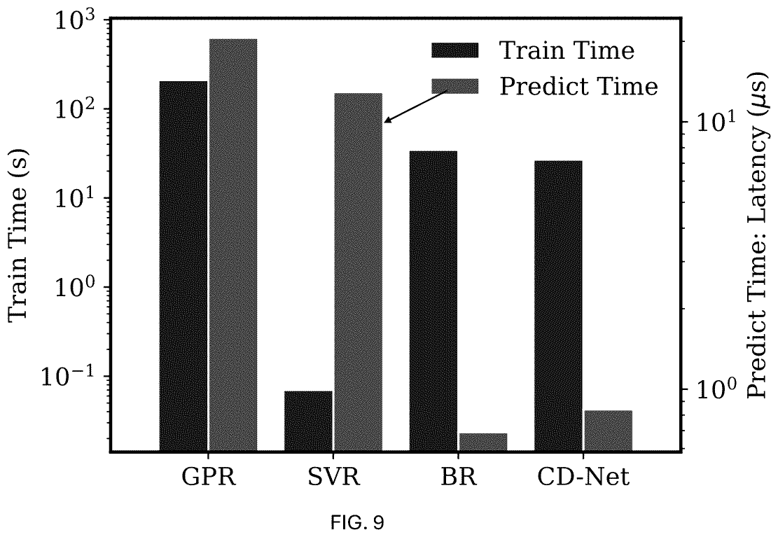

The measured computational train and prediction times of the tested models is shown in FIG. 9, which is a graph of train time in seconds vs. predicted time latency in us vs. network type. This figure shows comparisons of computational efficiency in terms of a) Predict time (also called inference latency) and b) Train time of the tested methods. The ideal prediction method has the lowest prediction error and train time with high accuracy. The model train time represents the average duration required for the tested models to be trained using the selected NASA dataset. CD-Net and BR demonstrated the shortest model prediction times over 1000 trials, as depicted in the plots of FIG. 9. In terms of training time, SVR was found to be the fastest, while CD-Net and BR exhibited the lowest inference latency. The model train time is the average time it takes for the tested models to be trained on the chosen NASA dataset. Here, CD-Net and BR exhibited the shortest model prediction times over 1000 trails. Based on plots from FIG. 9, SVR is the fastest in terms of training time, and CD-Net and BR have the lowest inference latency. In applications such as deployment onboard BMS, low inference latency is highly desirable for model deployment, even if it requires longer training times (which can be mitigated through transfer learning) conducted off-site prior to deployment. Concerning on-board storage, CD-Net utilizes 3.5 kB, BR utilizes 9.1 kB, SVR utilizes 47.1 kB, and GPR utilizes 1.7 MB. Consequently, CD-Net emerges as a favorable choice for online SoH prediction due to its accurate RUL prediction, low model inference latency, and minimal on-board storage space requirements compared to alternative options.

Those having ordinary skill in the art will recognize that numerous modifications can be made to the specific implementations described above. The implementations should not be limited to the particular limitations described. Other implementations may be possible.

1. A method of predicting battery end of life based on a small dataset, comprising:
training a deep learning network using a plurality of a priori generated training datasets;
receiving new testing datasets including current vs. time datapoints in real-time as one or more batteries representing a battery pack design of choice are tested to thereby generate a plurality of new unseen datasets; and
applying the new unseen datasets to the trained deep learning network to thereby generate a prediction of a cycle representing end of life for said design of choice.

2. The method of claim 1, wherein the deep learning network is a neural network.

3. The method of claim 1, wherein the new unseen current vs. time datapoints are from one or more current sensors configured to measure current in one or more cells of a battery pack under test.

4. The method of claim 1, wherein the current vs. time datapoints are converted to capacity vs. cycle datapoints.

5. The method of claim 4, wherein the plurality of a priori generated training datasets include datapoints from a plurality of known battery designs.

6. The method of claim 5, wherein the plurality of training capacity vs. cycle datapoints include a flag representing an associated battery design to enable the deep learning network to be trained associated with a chemistry-specific design of choice, thus generating a trained chemistry-specific deep learning network.

7. The method of claim 6, wherein the trained chemistry-specific deep learning network receives the new unseen datasets corresponding to each of the associated chemistry-specific design of choice based on a flag representing the chemistry-specific design of choice.

8. The method of claim 7, wherein the deep learning network is blind to battery design when receiving the plurality of a priori generated training datasets.

9. The method of claim 8, wherein the plurality of a priori generated training datasets generates a trained chemistry-independent deep learning network.

10. The method of claim 9, wherein the trained chemistry-independent deep learning network receives the plurality of new unseen datasets without any indication of battery design.

11. A system for predicting battery end of life based on a small dataset, comprising:
one or more current sensors providing real-time current data;
a testbed configured to test one or more batteries based on a prescribed testing schedule;
a processing system including a processor executing instruction residing on a non-transitory memory, the processor configured to receive real-time current data;
the processor configured to communicate with a deep learning network, where the processor is configured to:
train the deep learning network using a plurality of a priori generated training datasets;
receive new testing datasets in real-time including current vs. time datapoints as one or more batteries representing a battery pack design of choice are tested to thereby generate the new unseen datasets; and
apply the new unseen datasets to the trained deep learning network to thereby generate a prediction of a cycle representing end of life for said design of choice.

12. The system of claim 11, wherein the deep learning network is a neural network.

13. The system of claim 11, wherein the new current vs. time datapoints are from the one or more current sensors configured to measure current in one or more cells of a battery pack under test.

14. The system of claim 11, wherein the new current vs. time datapoints are converted to capacity vs. cycle datapoints.

15. The system of claim 14, wherein the plurality of a priori generated training datasets include datapoints from a plurality of known battery designs.

16. The system of claim 15, wherein the plurality of training capacity vs. cycle datapoints include a flag representing an associated battery design to enable the deep learning network to be trained associated with a chemistry-specific design of choice, thus generating a trained chemistry-specific deep learning network.

17. The system of claim 16, wherein the trained chemistry-specific deep learning network receives the new unseen datasets corresponding to each of the associated chemistry-specific design of choice based on a flag representing the chemistry-specific design of choice.

18. The system of claim 17, wherein the deep learning network is blind to battery design when receiving the plurality of a priori generated training datasets.

19. The system of claim 18, wherein the plurality of a priori generated training datasets generates a trained chemistry-independent deep learning network.

20. The system of claim 19, wherein the trained chemistry-independent deep learning network receives the plurality of new unseen datasets without any indication of battery design.
